(19) United States
(12) Patent Application Publication
(10) Pub. No.: US 2012/0002361 A1
(43) Pub. Date: Jan. 5, 2012

(54) PIVOTING DISPLAY DEVICE

(75) Inventors: Yusuke Tanaka, Osaka (JP); Hiroshi Tsuda, Nara (JP)

(73) Assignee: Panasonic Corporation, Osaka (JP)

(21) Appl. No.: 13/174,791

(22) Filed: Jul. 1, 2011

(30) Foreign Application Priority Data
Jul. 2, 2010 (JP) 2010-151781

(51) Int. Cl. H05K 5/02

(52) U.S. Cl. 361/679.01

(57) ABSTRACT

An object of the present invention is to make available a pivoting display device which enables a display unit to be assuredly stowed even by using a relatively small elastic component, and which has enhanced reliability and is space-saving. When a power switch becomes off, a monitor which can be stowed is swung by urging force from a coil spring. In an initial stage in which counter-electromotive force Vm induced by a motor is greater than on-voltage of a FET, the counter-electromotive force Vm acts as rotation resistance for the motor. When the monitor approaches a stowage position, the rotating speed of the motor is reduced. Therefore, bias voltage of the FET is reduced due to reduction of the counter-electromotive force Vm, and the braking force imposed on the motor by the counter-electromotive force Vm is gradually reduced, thereby increasing pivoting speed.

### CROSS REFERENCE TO RELATED APPLICATION

The disclosure of Japanese Patent Application No.2010-151781, filed on July 2, 2010, is incorporated herein by reference.

### BACKGROUND OF THE INVENTION

1. Field of the Invention

The present invention relates to pivoting display devices that are mounted to the ceiling area of cabins of, for example, passenger airplanes, and that swing display units open from a stowage position to a display position when used.

2. Description of the Background Art

In recent years, display devices are often mounted in transportation means such as airplanes, trains, busses, and passenger boats to provide passengers with video image content and information.

Passengers increasingly desire to individually enjoy various video images in transportation means, and it is desired to provide pivoting display devices having thin lightweight display units which can be mounted in minimized space.

Therefore, especially in passenger airplanes, pivoting display devices in which the display unit, stowed below the baggage rack/compartment in the ceiling area above the cabin seats, is drawn out and used for video image distribution services etc. and is stowed again in the ceiling area after use, are becoming widespread, and various configurations have appeared.

The pivoting display devices described above are configured to be driven by drive units when power switches of the devices are powered on, and such that the display unit, which is in flat rectangular platelike form, thereby pivots centered on one side of the unit and is drawn out from the stowing portion of the ceiling area above the seats, and after being used to display the video images of a video image distribution service or the like, at an angle for easy viewing by a passenger, pivots again to be stowed into its original ceiling area.

Further, in airplanes, safety is regarded to be of the utmost importance, and display devices are no exception, wherein a situation in which power supply to a cabin is interrupted while the display units as described above are being used would demand that the display devices be immediately retracted into the stowing areas.

In response to demands of this sort, pivoting display devices are suggested in which energy for stowage is accumulated in elastic components when the display units are drawn out to display positions, and the display devices are automatically stowed into the stowing portions when the display devices are powered off after used, or when power supply to the cabins is interrupted (see Japanese Laid-Open Patent Publication Nos. 4-5142, 2006-88797, and 2009-166582).

The display devices as described above are configured such that the stowing speed of the display units is restricted so as to prevent, while a display unit is being stowed, passengers on the seats beneath the unit from being injured by bumping against the display unit or from getting some portion of their body caught in the stowing area, due to the display unit being stowed too rapidly under the elastic energy accumulated in the elastic components.

### SUMMARY OF THE INVENTION

For example, in the technique described in Japanese Laid-Open Patent Publication No. 4-5142, a gear damper is used so as to obtain smooth pivoting when the display unit is stowed.

However, the gear damper is configured so as to include a plurality of gears, and increase a frictional force due to a centrifugal force. Therefore, the gear damper has a complicated configuration, and less reliability.

Further, in the technique described in Japanese Laid-Open Patent Publication No. 2006-88797, a cord is wound around a brake drum, and a frictional force obtained by adjusting the tensile force exerted on the cord is utilized.

However, when braking utilizing a friction between the brake drum and the cord is repeated over a long time period, the cord is worn out. Therefore, the durability and wear resistance are poor, and it is difficult to ensure reliability in long term use, and further mechanism for protection in the case of the cord being broken is necessary.

Furthermore, in the technique described in Japanese Laid-Open Patent Publication No.2009-166582, a braking force is obtained by regeneration of a counter-electromotive force generated in a DC electromotor when the display unit is being stowed.

However, the braking force obtained by the regeneration of the counter-electromotive force continues to be applied to the DC electromotor until the display unit stops at a stowage position. Further, when the display unit has pivoted from a display position so as to be almost horizontal, a moment of force for pivoting on a pivot of the display unit the display unit open toward the display position due to the weight of the display unit itself is applied to the elastic component. Therefore, toward the end of the stowing operation, energy for stowage accumulated in the elastic component balances with a reaction force including a resultant force of the braking force and the rotation moment due to its own weight of the display unit, so that the stowing speed of the display unit is reduced.

Further, in such a configuration, when energy accumulated in the elastic component for stowage is reduced due to aged deterioration of the elastic component, the display unit cannot be automatically stowed in the stowing portion by checking the reaction force described above.

Further, a large elastic component which can accumulate sufficient energy needs to be used so as to assuredly stow the display unit in the stowing portion. When a large elastic component is used, a large drive section which exerts a force for enabling the large elastic component to be driven is necessary. Therefore, the weight and size of the configuration cannot be reduced.

The present invention is made to solve the afore-mentioned problems, and an object of the present invention is to make available a pivoting display device which allows a display unit to be assuredly stowed even with a relatively small elastic component, by reducing a braking force for pivoting while the display unit is being stowed, and which has enhanced reliability and is space-saving.

In order to attain the aforementioned object, a pivoting display device of the present invention includes: a display unit supported enabling the unit to pivot between a display position and a stowage position; a drive section having a DC electromotor for rotating, by means of a supply of power, in a forward direction to pivot the display unit from the stowage position to the display position; an elastic component urging the display unit via the drive section in a direction in which the display unit is pivoted from the display position to the stowage position; and a counter-electromotive force control circuit for controlling counter-electromotive force generated by the DC electromotor rotating in reverse via the drive section under the urging force of the elastic component, when power supply to the DC electromotor is interrupted, and, in the pivoting display device, a control is performed such that the urging force of the elastic component becomes maximum with the display unit in the display position, and reduces in accordance with the display unit approaching the stowage position.

In the pivoting display device having the features described above, even when no motive power is applied to the pivoting display device, if a braking force for pivoting is reduced when the display unit is being stowed, even a relatively small elastic component enables the display unit to be assuredly stowed, thereby realizing enhanced reliability and space-saving.

Further, in order to attain the object described above, process of each component of the pivoting display device of the present invention as described above can be implemented as a deploy/stow method of the pivoting display device which includes a series of process steps. The method is provided in a form of a program for causing a computer to execute the series of process steps. The program may be stored in a computer-readable storage medium and introduced into a computer.

As described above, according to the present invention, energy for stowage is accumulated in an elastic component when a display unit is drawn out to a display position, and the display unit can be automatically stowed into a stowing portion after used or when passage of electric current to a cabin is interrupted. Further, even when an urging force is reduced due to aged deterioration of the elastic component, a force for braking the pivoting of the display unit can be reduced when the display unit is being stowed, thereby assuredly stowing the display unit. Thus, the pivoting display device can be realized which can exert the above-described effects, has enhanced reliability, and is space-saving.

### BRIEF DESCRIPTION OF THE DRAWINGS

FIG. 1 is a block diagram illustrating a configuration of a counter-electromotive force control unit of a pivoting display device according to a first embodiment of the present invention;

FIG. 2 is a diagram schematically illustrating a configuration of the pivoting display device according to the first embodiment of the present invention;

FIG. 3 is a cross-section view of the pivoting display device according to the first embodiment of the present invention;

FIG. 4 is a block diagram illustrating the configuration of the counter-electromotive force control unit of the pivoting display device according to the first embodiment of the present invention;

FIG. 5 is a block diagram illustrating an operation performed by the counter-electromotive force control unit of the pivoting display device according to the first embodiment of the present invention;

FIG. 6 is a block diagram illustrating the operation performed by the counter-electromotive force control unit of the pivoting display device according to the first embodiment of the present invention;

FIG. 7 is a sequence chart illustrating an operation performed by the pivoting display device according to the first embodiment of the present invention;

FIG. 8 is a block diagram illustrating a configuration of a counter-electromotive force control unit of a pivoting display device according to a second embodiment of the present invention:

FIG. 9 is a cross-sectional view illustrating an operation performed by the pivoting display device according to the second embodiment of the present invention;

FIG. 10 is a sequence chart illustrating the operation performed by the pivoting display device according to the second embodiment of the present invention;

FIG. 11 is a block diagram illustrating an operation performed by the counter-electromotive force control unit of the pivoting display device according to the second embodiment of the present invention; and

FIG. 12 is a block diagram illustrating a configuration of a counter-electromotive force control unit of a pivoting display device according to a third embodiment of the present invention.

### DESCRIPTION OF THE PREFERRED EMBODIMENTS

Hereinafter, embodiments of the present invention will be described with reference to the drawings.

In the embodiments, an exemplary case in which the present invention is applied, especially, to a passenger airplane will be described. However, the present invention is not limited thereto. The present invention is applicable to various transportation means such as trains, busses, and passenger boats, as well as airplanes.

(First embodiment)

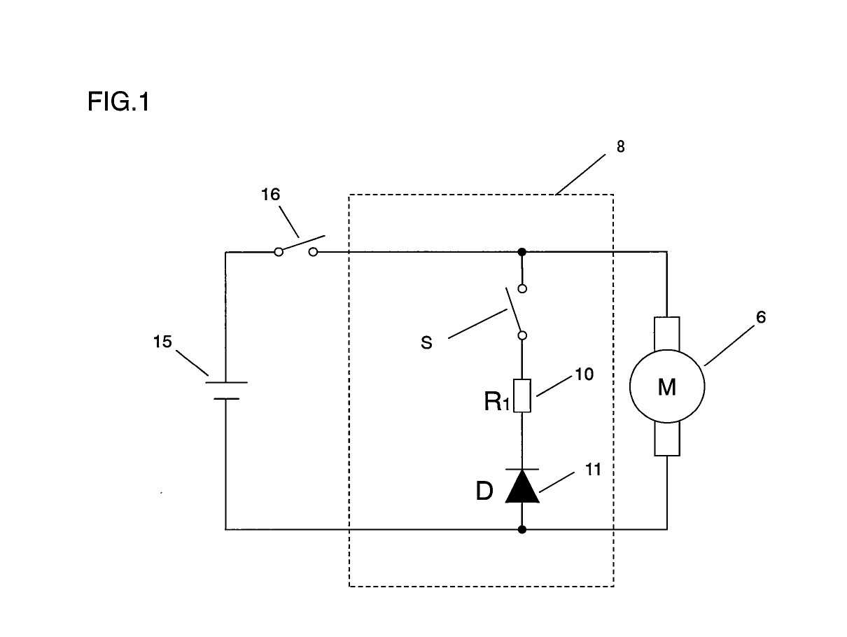

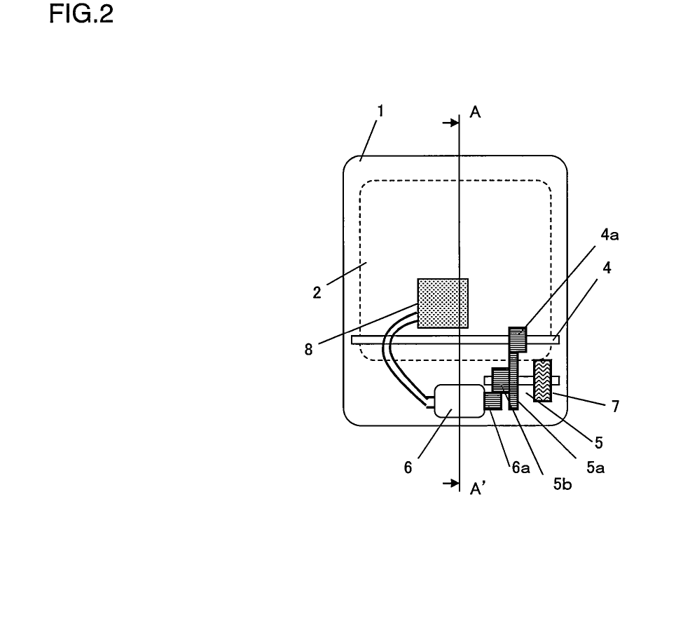

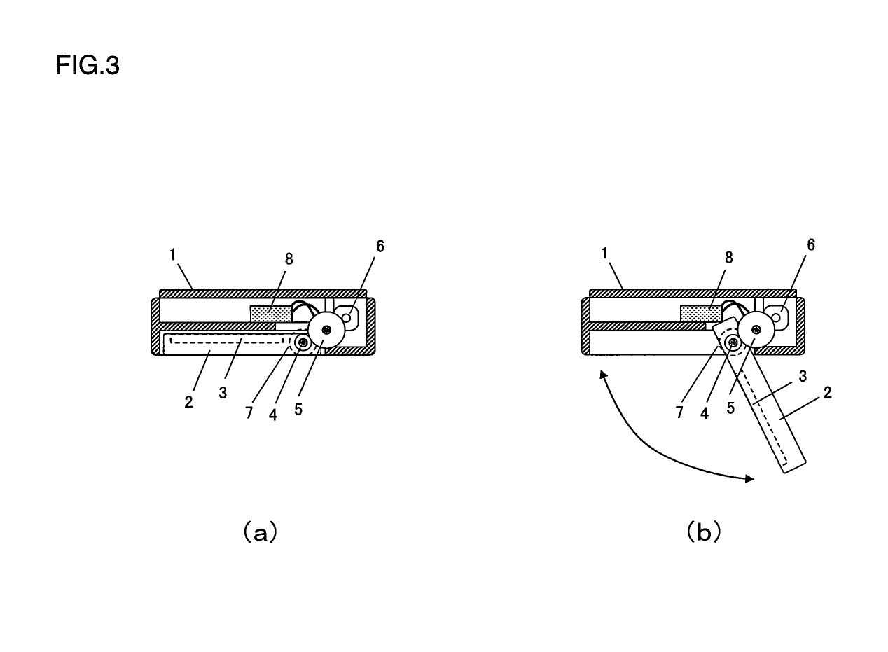

FIG. 1 shows a configuration of a counter-electromotive force control unit of a pivoting display device according to a first embodiment of the present invention, which is stowed in stowing portion provided in a ceiling area of a passenger airplane, especially in a stowing portion below a baggage rack/compartments. FIG. 2 and FIG. 3 show a schematic configuration thereof.

FIG. 2 is a top view of the pivoting display device, and FIG. 3 is a cross-sectional view taken along a line A-A′ of FIG. 2. FIG. 3(a) shows a display unit in a stowed state, and FIG. 3(b) shows the display unit in a used state.

As shown in the drawings, a monitor 2 acting as the display unit is mounted below a body frame 1 of the pivoting display device, and is mounted, as a whole, in the stowing portion in a not-illustrated ceiling area of the passenger airplane, especially in the stowing portion below the baggage rack/compartments.

The monitor 2 is shaped like a rectangular flat plate as a whole, and has a display unit 3, such as an LCD, shaped like a panel. In the monitor 2, a coaxial pivot 4 is provided at both ends of the rectangular shape near one of the sides of the monitor 2 so as to be supported enabling the monitor to pivot, by bearings (not illustrated) provided on both sides of the body frame 1. The monitor 2 swings open (deploys) by means of a drive mechanism 5 provided on the monitor 2 so as to position its screen at an angle at which passengers are allowed to easily view the screen, when used. The monitor 2 is stowed again below the body frame 1 after used.

In the drive mechanism 5, a gear 5a engages with a gear 4a provided on the pivot 4, and a gear 5b coaxial with the gear 5a engages with a gear 6a of a motor 6 which drives the drive mechanism 5, thereby conveying rotation. The motor 6 is a DC electromotor, and is controlled by a switch described below being ON/OFF, and by means of a counter-electromotive force control unit 8.

Further, a coil spring 7 which acts as an elastic component is mounted so as to be coaxial with the drive mechanism 5, and urges the gear 5a in a direction in which the monitor 2 is restored to a stowage position.

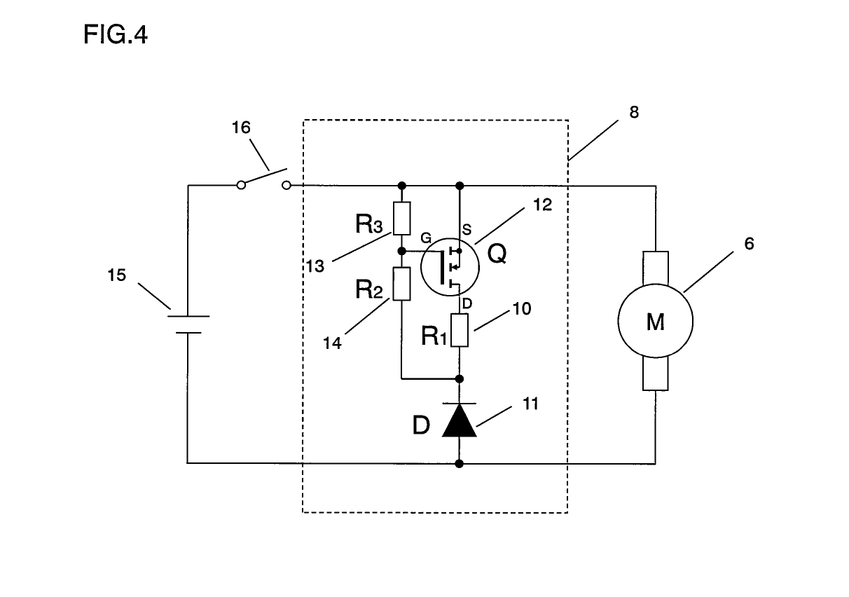

FIG. 1 is a block diagram illustrating a configuration of the counter-electromotive force control unit 8. As shown in FIG. 1, the counter-electromotive force control unit 8 includes: a resistance 10 for regulating electric current of a counter-electromotive force generated in the motor 6; a diode 11 which acts as a rectifier for regulating flowing of electric current to the counter-electromotive force control unit 8 when the motor 6 rotates forward; and a switch S for controlling electric current. As the switch S, any type of switch can be used. A FET as described in the present embodiment may be used, or a circuit switch as described in a second embodiment described below may be used. In the present embodiment, as shown in FIG. 4, a FET 12 which is an electric current control element is used as the switch S, and resistances 13 and 14 are provided for adjusting bias voltage of the FET 12. Further, reference numeral 15 denotes a power supply of the pivoting display device, and reference numeral 16 denotes a power switch of the pivoting display device.

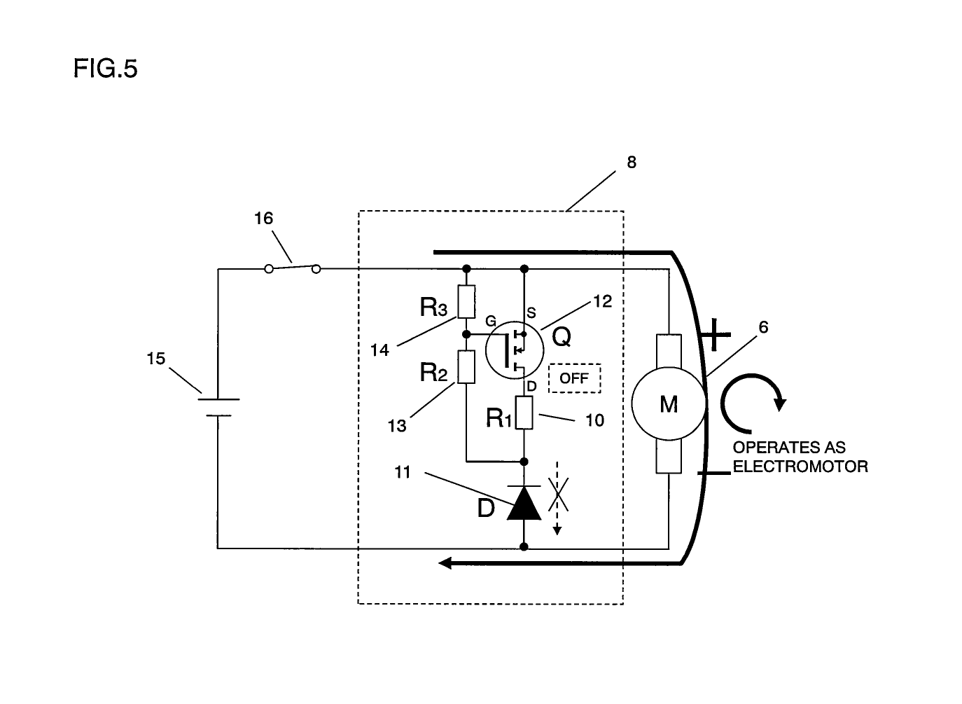

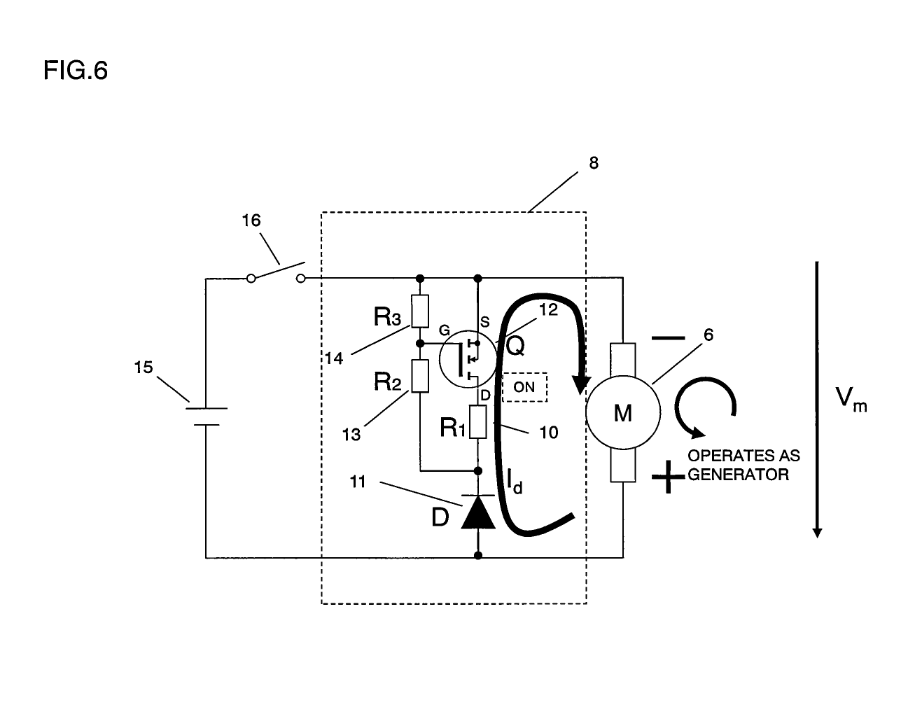

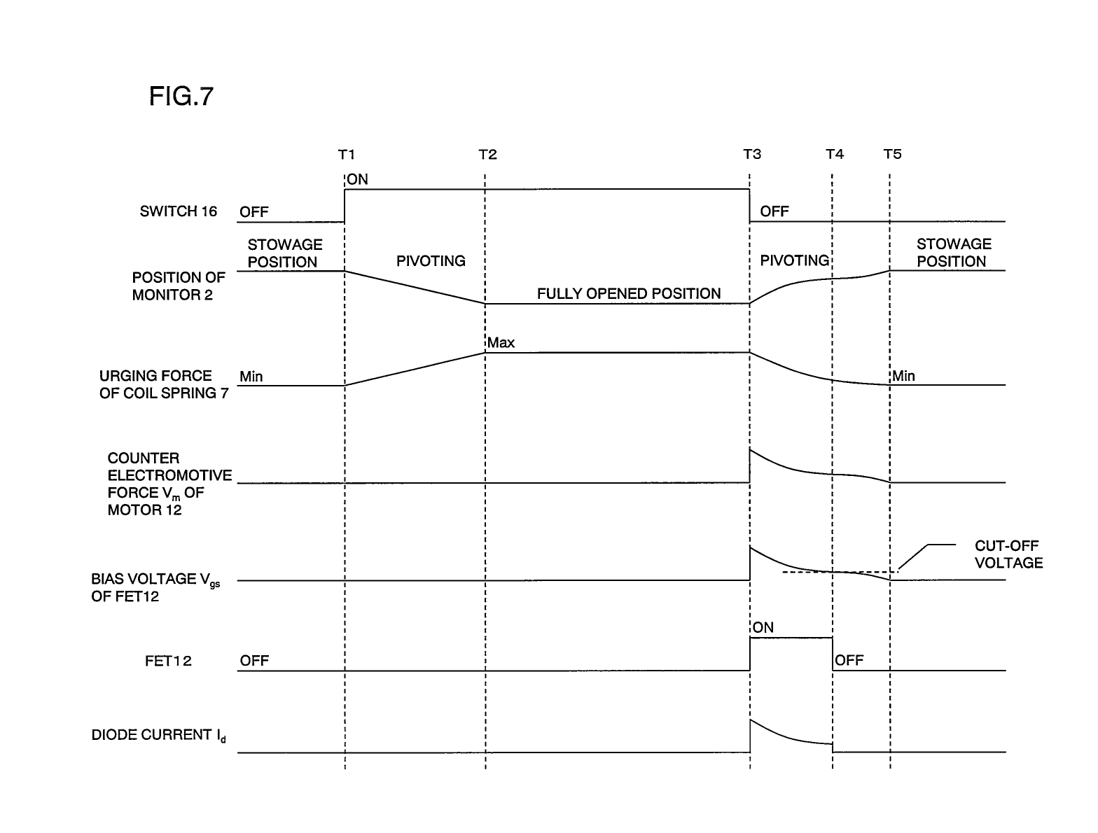

An operation performed by the pivoting display device having the above-described configuration will be described with reference to FIG. 3, block diagrams shown in FIG. 5 and FIG. 6, and a sequence chart shown in FIG. 7.

Firstly, an operation of the display unit being pivoting open will be described. In FIG. 5, the power switch 16 is on (shorts out), and the motor 6 rotates forward (T1 in FIG. 7), so as to pivot the monitor 2 to a display position (FIG. 3(b)).

At this time, a reverse-direction voltage is applied to an electric circuit connected in series with the diode 11, and no electric current flows. When the monitor 2 has been pivoted up to the display position, an urging force accumulated in the coil spring 7 is maximized (T2 in FIG. 7).

Next, an operation of the display unit being stowed will be described. In FIG. 6, when the power switch 16 becomes off (open), the monitor 2 pivots toward the stowage position (FIG. 3(a)), by utilizing the energy accumulated in the coil spring 7, so that force for reverse rotation is applied to the motor 6 (T3 in FIG. 7). At this time, a counter-electromotive force is generated in the motor 6, and forward-direction voltage is applied to the electric circuit connected in series with the diode 11, and an electric current Id flows, so that a gate of the FET 12 is biased.

When a bias voltage becomes higher than an on-voltage of the FET 12, the FET 12 becomes on, and a counter-electromotive force Vm induced in the motor 6 circulates in a closed loop including the diode 11 and the FET 12, so that a force for forward rotation is applied to the motor 6 which is reversely rotating.

This force acts as a braking force when the monitor 2 is being stowed, and the monitor 2 pivots at a safe speed at the beginning of the pivoting for stowage.

When the monitor 2 has pivoted to some degree, and approaches the ceiling area so as to be horizontal, the pivoting speed of the monitor 2 is reduced due to reduction in energy accumulated in the coil spring 7 and due to a rotation moment for pivoting the monitor 2 in the vertical direction due to its own weight.

The reduction in pivoting speed causes reduction of the counter-electromotive force induced by the motor 6, so that a voltage applied to the gate of the FET 12 is also reduced.

The FET 12 is an element for controlling, by a gate voltage, an electric current flowing between a drain and a source, and the electric current Id generated by the counter-electromotive force induced by the motor 6 is greatly restricted so as to reduce electric current flowing in the FET 12 as the pivoting speed is reduced, resulting in gradual reduction of the braking force which is applied to the motor 6 due to the counter-electromotive force.

At a certain time, a bias voltage Vgs of the FET 12 becomes lower than a gate cut-off voltage (T4 in FIG. 7).

Thus, the closed loop for the counter-electromotive force is released, and no electric load is imposed on the motor 6, so that the pivoting speed can be increased. Therefore, the monitor 2 can be assuredly stowed in the stowage position (T5 in FIG. 7).

In the above description, the resistances 10, 13, and 14 are each a single element in the counter-electromotive force control unit 8. However, a resistance array having a plurality of resistances connected in parallel with each other may be used. In this case, even when some of the resistances included in the resistance array are damaged, the circuit configuration can be maintained by the other resistances, thereby enabling enhancement of reliability.

(Second embodiment)

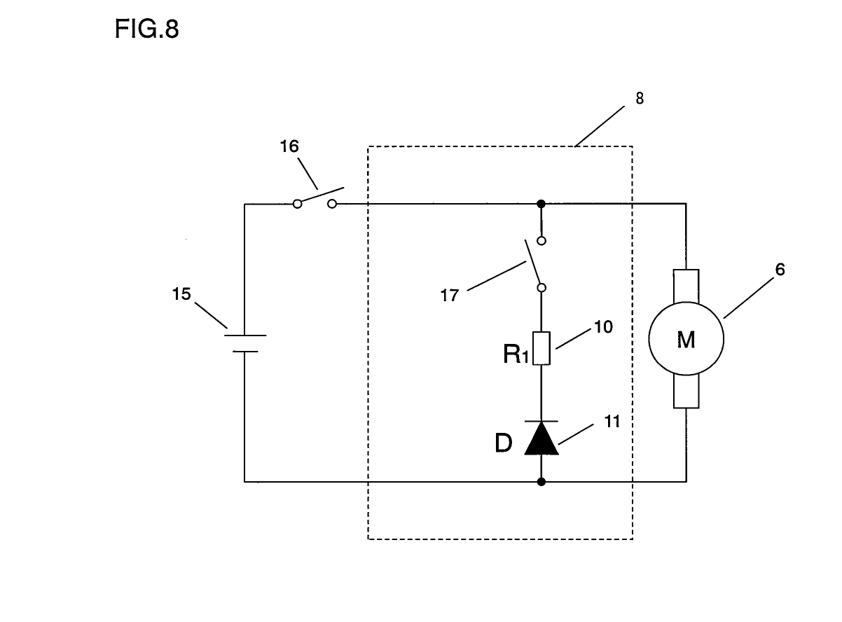

FIG. 8 is a block diagram illustrating a configuration of a counter-electromotive force control unit of a pivoting display device according to a second embodiment of the present invention. In FIG. 8, the same components as described in the first embodiment are denoted by the same reference numerals as shown in the block diagram of FIG. 4 illustrating the configuration of the counter-electromotive force control unit.

In FIG. 8, reference numeral 6 denotes a motor acting as a DC electromotor in a drive section, reference numeral 10 denotes a resistance for regulating electric current of a counter-electromotive force generated in the motor 6, reference numeral 11 denotes a diode acting as a rectifier for regulating flowing of electric current to the counter-electromotive force control unit when the motor 6 rotates forward, reference numeral 16 denotes a power switch of the pivoting display device, and reference numeral 15 denotes a power supply of the pivoting display device. The above-described components are similar to those shown in FIG. 4.

The configuration shown in FIG. 8 is different from the configuration shown in FIG. 4 in that the resistances 13 and 14, and the FET 12 acting as the switch S which are included in the counter-electromotive force control unit 8, are replaced with a circuit switch 17, in the configuration shown in FIG. 8.

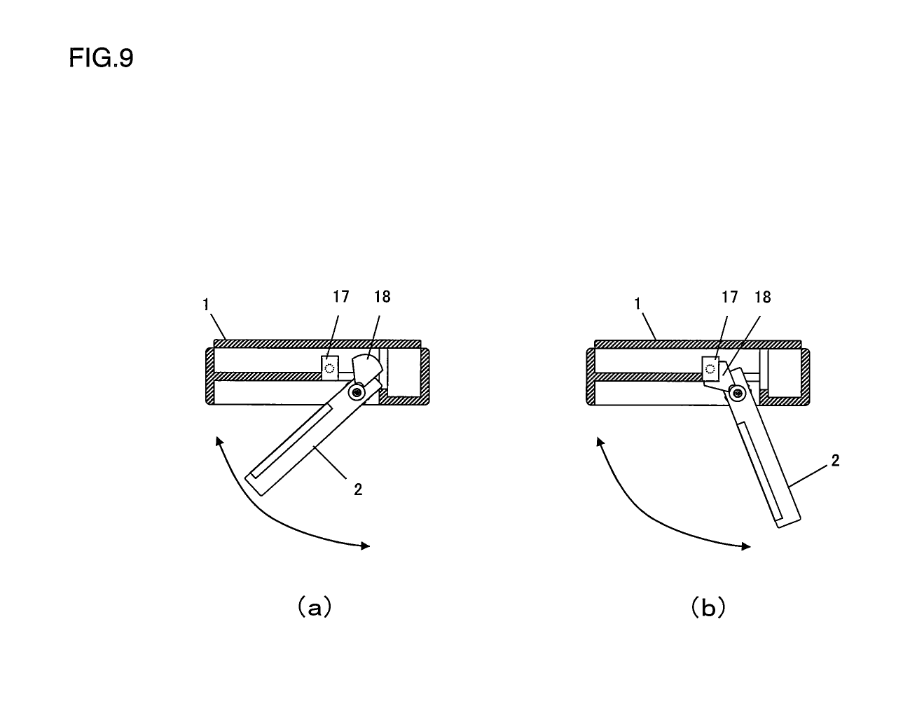

Further, FIG. 9 is a cross-sectional view illustrating an opened state and a closed state of the pivoting display device. FIG. 9(a) shows a state in which the display unit is pivoting open or closed, and FIG. 9(b) shows the display unit in a used state.

Similarly to FIG. 8, the configuration shown in FIG. 9 is different from the configuration shown in FIG. 3 for the first embodiment in that the circuit switch 17, and a press-down part 18 for turning the circuit switch 17 on or off are provided instead of the counter-electromotive force control unit 8 in the configuration shown in FIG. 9. In FIG. 9, illustration of the components other than the circuit switch 17, the press-down part 18, the body frame 1, and the monitor 2 is omitted.

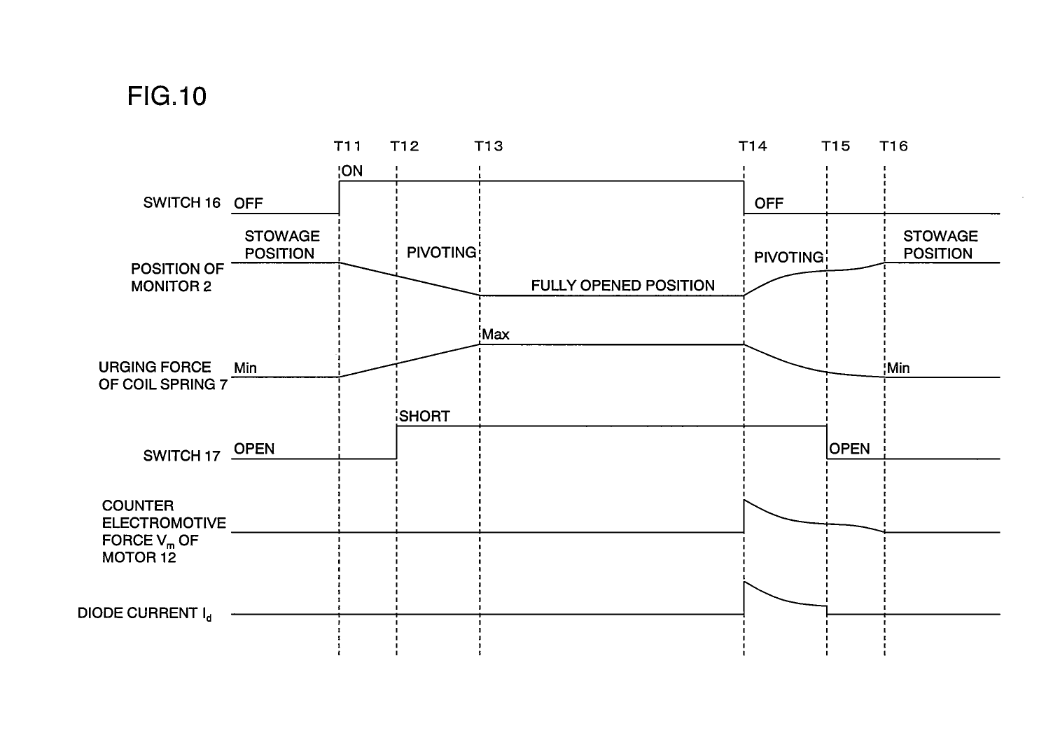

An operation performed by the pivoting display device having the above-described configuration will be described with reference to FIG. 8, FIG. 9, and a sequence chart of FIG. 10.

Firstly, an operation of the display unit being pivoting open will be described. In FIG. 9, the power switch 16 is on (shorts out), and the motor 6 rotates forward (T11 in FIG. 10), so as to pivot the monitor 2 to the display position (FIG. 9(b)).

At this time, the circuit switch 17 is open until the monitor 2 reaches a predetermined position, and when and after the monitor 2 has reached the predetermined position, the circuit switch 17 shorts out by means of the press-down part 18 (T12 in FIG. 10).

In the electric circuit which is connected in series with the diode 11, when the circuit switch 17 is open, electric connection does not occur, so that no electric current flows, and also when the circuit switch 17 shorts out, a reverse-direction voltage is applied to the diode 11, and no electric current flows. When the monitor 2 has pivoted up to the display position, the urging force accumulated in the coil spring 7 is maximized (T13 in FIG. 10).

Next, an operation of the display unit being stowed will be described. In FIG. 9(b), when the power switch 16 becomes open, the monitor 2 pivots toward the stowage position by utilizing the energy accumulated in the coil spring 7 (FIG. 9(a)), so that force for reverse rotation is applied to the motor 6 (T14 in FIG. 10).

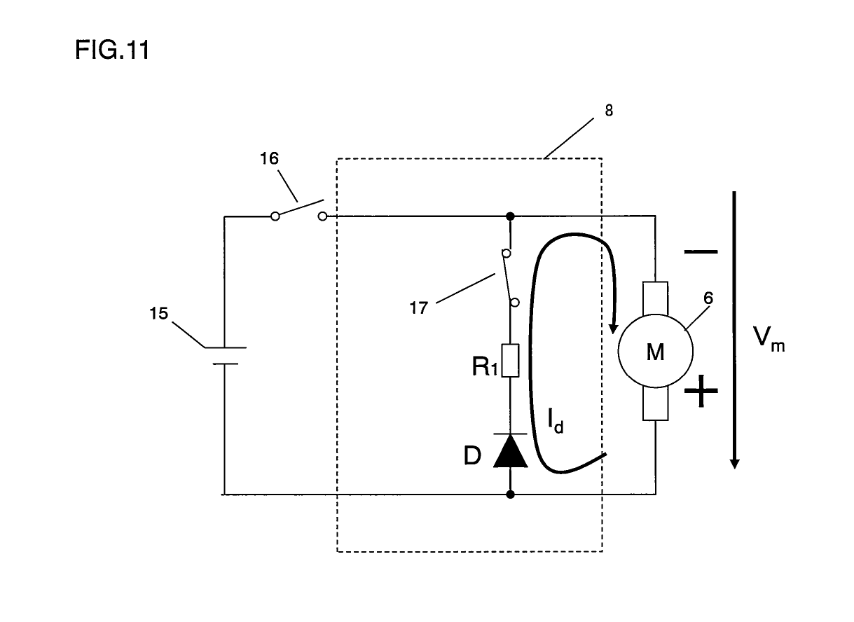

At this time, as shown in the block diagram of FIG. 11, until the monitor 2 reaches the predetermined position, the circuit switch 17 shorts out, and further a counter-electromotive force is generated in the motor 6, and the electric current Id generated by the counter-electromotive force induced by the motor 6 thus circulates in a closed loop including the motor 6 and the electric circuit connected in series with the diode 11.

Thus, a force for forward rotation is applied to the motor 6 which is reversely rotating. This force acts as a braking force when the monitor 2 is being stowed. The monitor 2 pivots at a safe speed at the beginning of the pivoting for stowage.

When the monitor 2 has pivoted to some degree, and approaches the ceiling area so as to be horizontal, the pivoting speed of the monitor 2 is reduced due to reduction in energy accumulated in the coil spring 7 and due to a rotation moment for pivoting the monitor 2 in the vertical direction due to its own weight.

When the monitor 2 has reached the predetermined position, the circuit switch 17 becomes open by means of the coil spring 7, and the closed loop for the counter-electromotive force is released, and no electric load is imposed on the motor 6, so that the pivoting speed can be increased (T15 in FIG. 10).

Thus, the monitor 2 can be assuredly stowed in the stowage position (T16 in FIG. 10).

It is to be noted that, as in the first embodiment, although the resistance 10 shown in FIG. 8 is a single element in the above description, a resistance array having a plurality of resistances connected in parallel with each other may be used. In this case, even when some of the resistances included in the resistance array are damaged, the circuit configuration can be maintained by the other resistances, thereby enabling enhancement of reliability.

(Third embodiment)

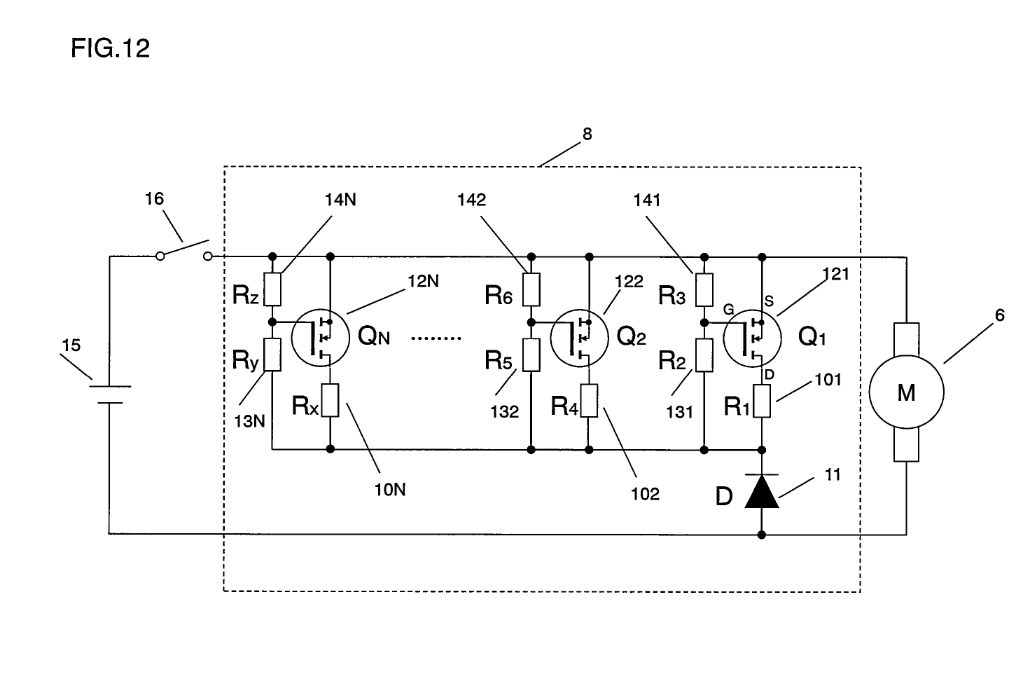

FIG. 12 is a block diagram illustrating a configuration of a pivoting display device according to a third embodiment of the present invention. In FIG. 12, the same components as described in the first embodiment are denoted by the same reference numerals as those of the configuration shown in the block diagram of FIG. 4.

The configuration shown in FIG. 12 is different from the configuration shown in FIG. 4 for the first embodiment in that a plurality of circuits each formed by the FET 12 and the resistances 10, 13, and 14 in the counter-electromotive force control unit 8 are connected in parallel with the motor 6, and the FETs 12 and the resistances 10, 13, and 14 included in the plurality of circuits are represented by FETs 121 to 12N, resistances 101 to 10N, 131 to 13N, and 141 to 14N, respectively.

Values of the resistances 101 to 10N, 131 to 13N, and 141 to 14N connected to the FETs 121 to 12N, respectively, are individually determined, to obtain different control characteristics. Thus, the stowing speed can be controlled more minutely as compared to in the counter-electromotive force control unit 8 having a single FET.

Although in the above description the counter-electromotive force control unit of the present embodiment is formed by the FETs and the resistances, the counter-electromotive force control unit may be formed by the switches and the press-down parts as described in the second embodiment.

It is to be noted that the components of the pivoting display device according to each of the first to the third embodiments described above may be implemented as an integrated circuit such as an LSI, or may be made into one chip by using a dedicated signal processing circuit. Further, the pivoting display device according to each of the first to the third embodiments may be realized by chips corresponding to functions of the respective components. The LSI in the above description may be referred to as an IC, a system LSI, a super LSI, or an ultra LSI, depending on the difference in the degree of integration. Furthermore, the method for circuit-integration is not limited to LSI, and may be realized by a dedicated circuit or a general-purpose processor. A field programmable gate array (FPGA) that can be programmed after manufacture or a reconfigurable processor that enables connections and settings of the circuit cells in the LSI to be reconfigured may be used. Further, in a case where another integration technology replacing LSI becomes available due to improvement of a semiconductor technology or due to the emergence of another technology derived therefrom, it goes without saying that integration of the functional blocks may be performed using such a new integration technology.

The present invention is greatly useful as a pivoting display device including a thin display unit for providing various information to passengers in, for example, transportation means such as passenger airplanes, trains, busses, and passenger boats.

What is claimed is:

1. A pivoting display device comprising:
a display unit supported enabling the unit to pivot between a display position and a stowage position;
a drive section having a DC electromotor for rotating, by means of a supply of power, in a forward direction to pivot the display unit from the stowage position to the display position;
an elastic component urging the display unit via the drive section in a direction in which the display unit is pivoted from the display position to the stowage position; and
a counter-electromotive force control circuit for controlling counter-electromotive force generated by the DC electromotor rotating in reverse via the drive section under the urging force of the elastic component, when a supply of power to the DC electromotor is interrupted, wherein
the urging force of the elastic component becomes maximum with the display unit in the display position, and reduces in accordance with the display unit approaching the stowage position; and
the counter-electromotive force control circuit controls the DC electromotor in such a way that the counter-electromotive force is maximum with the display unit in the display position, and reduces in accordance with the display unit approaching the stowage position.

2. The pivoting display device according to claim 1, wherein:
the counter-electromotive force control circuit includes a switch; and
the counter-electromotive force control circuit turns the switch off when the display unit has approached a predetermined position apart from the stowage position.

3. The pivoting display device according to claim 2, wherein:
the switch is an FET; and
the counter-electromotive force control circuit further includes a resistance for regulating the on-/off-points of the FET, and a diode for passing electric current in the direction of the counter-electromotive force.

4. The pivoting display device according to claim 3, wherein a plurality of circuits each constituted from an FET, and the resistance for regulating the on-/off-points of the FET is connected in parallel with the DC electromotor.

5. The pivoting display device according to claim 2, wherein:
the switch is a circuit switch switching on/off according to pivoting of the display unit; and
the counter-electromotive force control circuit further includes
a resistance for regulating electric current in the counter-electromotive force control circuit, and
a diode for passing electric current in the direction of the counter-electromotive force.

6. The pivoting display device according to claim 5, wherein a switch press-down part, secured to the display unit, for turning the circuit switch on/off, is provided in the vicinity of the point about which the display unit pivots.

7. The pivoting display device according to claim 1, wherein the elastic component is a spring.

8. A method of deploying/stowing a pivoting display device swinging between a display position and a stowage position, the deploy/stow method comprising:
a deploying step of swinging a display unit, supported enabling the unit to pivot between the display position and the stowage position, from the stowage position to the display position, by means of a DC electromotor rotated in a forward direction by a supply of power, and of urging the display unit, when it has been swung as far as the display position, such as to apply a maximum urging force to the display unit, by means of an elastic component urging the display unit in a direction in which it is swung from the display position to the stowage position;
a control step of controlling, by means of a counter-electromotive force control circuit, counter-electromotive force that, when a supply of power to the DC electromotor is interrupted, the DC electromotor, rotating in reverse under said urging force, generates, and at the same time reducing said urging force;
a determination step of determining that the counter-electromotive force has become zero when the display unit has approached a predetermined position apart from the stowage position; and
a stowing step of stowing the display unit into the stowage position by means of the urging force with which the elastic component urges the display unit.

9. The deploy/stow method according to claim 8, wherein:
the counter-electromotive force control circuit includes a switch; and
the counter-electromotive force control circuit turns the switch off when the display unit has approached the predetermined position apart from the stowage position.
